(19) United States
(12) Patent Application Publication
(10) Pub. No.: US 2024/0174951 A1
(43) Pub. Date: May 30, 2024

(54) SUBSTRATE SURFACE TREATING SOLUTION, AND USING THE SAME, METHOD FOR MANUFACTURING CLEANED SUBSTRATE AND METHOD FOR MANUFACTURING DEVICE

(71) Applicant: Merck Patent GmbH, Darmstdt (DE)

(72) Inventors: Takafumi KINUTA, Kakegawa-shi (JP); Tatsuro NAGAHARA, Kakegawa-shi (JP)

(21) Appl. No.: 18/280,961

(22) PCT Filed: Mar. 8, 2022
(86) PCT No.: PCT/EP2022/055929

§ 371 Date: Sep. 8, 2023

(30) Foreign Application Priority Data
Mar. 11, 2021 (JP) 2021-039100

(51) Int. Cl. C11D 3/37; C11D 3/43

(52) U.S. Cl. CPC C11D 3/3723; C11D 3/43; C11D 2111/42

(57) ABSTRACT

To provide a substrate surface treating solution for efficiently cleaning a substrate. [Means for Solution] The substrate surface treating solution according to the present invention is a substrate surface treating solution comprising a basic compound (A) and a solvent (B), and the substrate surface treating solution is applied on a substrate to form a substrate surface treatment layer containing at least a part of the basic compound (A), and a substrate cleaning solution is applied on the substrate surface treatment layer and used for forming a substrate cleaning film.

### BACKGROUND OF THE INVENTION

### Technical Field

The present invention relates to a substrate surface treating solution, and using the same, a method for cleaning a substrate and a method for manufacturing a device.

### Background Art

Conventionally, in the process of manufacturing a substrate, debris may be generated, for example, by a lithography process or the like. Therefore, the substrate manufacturing process may include a cleaning step for removing particles on the substrate. In the cleaning step, there are methods such as a method for physically removing particles by supplying a cleaning solution such as deionized water (DIW: Deionized water) on the substrate and a method for chemically removing particles with chemicals. However, as patterns become finer and more complicated, they become more susceptible to physical or chemical damage.

As a substrate cleaning step, a method of forming a substrate cleaning film to hold particles in the film and removing the film by a remover has been studied. When the formed film is all dissolved by the remover, the particles held in the film can be reattached. Therefore, a method of partially dissolving the formed film and removing the undissolved portion in a solid state has been studied (for example, Patent Documents 1 and 2).

### PRIOR ART DOCUMENTS

### Patent Documents

[Patent document 1] JP 2019-212889 A

[Patent document 2] JP 2020-096165 A

### SUMMARY OF THE INVENTION

### Problems to be Solved by the Invention

The present inventors considered that when a substrate cleaning film is used for cleaning a substrate, the substrate cleaning film may not be peeled off well and particles may not be removed in the hydrophobic region of the substrate surface. Therefore, study of treating the substrate surface and making the substrate cleaning film easily peeled off was conducted.

Furthermore, under the technical background as described above, the present inventors considered that one or more problems required to be improved still exist in the technology of forming a film on the substrate and removing particles. Examples of these include the followings: the substrate cleaning film cannot be completely removed by a remover and remains on the substrate; there are some cases that the substrate cleaning film is difficult to be removed by a remover depending on the condition of the substrate surface and the shape of the unevenness etc. of the substrate; removal of particles is inefficient; forming a thin film or a conformal substrate surface treatment film on the substrate surface is difficult; when a highly soluble remover is used to remove the substrate cleaning film, the film itself may break and particles may be released; at the time of removing the substrate surface treatment film, the substrate surface may be damaged or the chemical and electrical properties of the substrate surface may change.

The present invention has been made based on the technical background as described above and provides a substrate surface treating solution.

### Means for Solving the Problems

The substrate surface treating solution according to the present invention comprises a basic compound (A) and a solvent (B):
wherein
the substrate surface treating solution is applied on a substrate to form a substrate surface treatment layer containing at least a part of the basic compound (A), and a substrate cleaning solution is applied on the substrate surface treatment layer and used for forming a substrate cleaning film.

The method for manufacturing a cleaned substrate according to the present invention comprises the following steps:
(1) applying the substrate surface treating solution according to the present invention on a substrate;
(2) forming a substrate surface treatment layer containing at least a part of a basic compound (A) from the substrate surface treating solution;
(3) applying a substrate cleaning solution on the substrate surface treatment layer;
(4) forming a substrate cleaning film from the substrate cleaning solution;
(5) removing the substrate cleaning film with a remover (1); and
(6) removing the substrate surface treatment layer with a remover (2).

The method for manufacturing a device according to the present invention comprises the above-mentioned method for manufacturing a cleaned substrate.

### Effects of the Invention

Using the substrate surface treating solution according to the present invention, it is possible to desire one or more of the following effects.

It is possible to effectively remove particles; it is possible to easily remove the substrate cleaning film even for hydrophobic substrates; it is possible to easily remove the substrate cleaning film even for a substrate having a uneven shape; it is possible to efficiently remove the substrate cleaning film from the substrate surface; it is possible to form a thin film and/or a conformal substrate surface treatment film; it is possible to prevent the substrate cleaning film itself from breaking and releasing particles using a highly soluble remover to remove the substrate cleaning film; it is possible not to damage the substrate surface and not to change the chemical and electrical properties of the substrate surface when removing the substrate surface treatment film; and it is possible to make lower the contact angle of the substrate surface.

### BRIEF DESCRIPTION OF THE DRAWING

FIG. 1 is a cross-sectional view schematically illustrating a method for manufacturing a cleaned substrate according to the present invention.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆-alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

Hereinafter, embodiments of the present invention are described in detail.

### Substrate Surface Treating Solution

The substrate surface treating solution according to the present invention comprises a basic compound (A) and a solvent (B). In a preferred embodiment of the substrate surface treating solution of the present invention, the solvent (B) comprises water (B-1); in a more preferable embodiment, the content of water (B-1) is 50 to 100 mass % based on the solvent (B).

The substrate surface treating solution according to the present invention is applied on a substrate to form a substrate surface treatment layer containing at least a part of the basic compound (A), and a substrate cleaning solution is applied on the substrate surface treatment layer and used for forming a substrate cleaning film. The substrate cleaning film holds particles and the like on a substrate to form a particle holding layer. In a preferred embodiment, removal of the particle holding layer is performed by being removed from on the substrate while holding particles without being completely dissolved by the remover (1). As a result, reattachment of particles is less likely to occur, and particles can be efficiently removed.

It is preferable that the substrate cleaning film is removed by a remover (1) and the substrate surface treatment layer is removed by a different remover (2).

The thickness of the substrate surface treatment layer formed by the substrate surface treating solution according to the present invention is preferably 0.001 to 2 nm (more preferably 0.001 to 0.5 nm). Although not to be bound by theory, it is assumed that being a thin film makes it possible to conformally form a layer even on an uneven substrate.

The substrate surface before applying the substrate surface treating solution may be hydrophilic or hydrophobic. When it is hydrophobic, the effects of the present invention can be more exhibited, which is preferable. The substrate before applying the substrate surface treating solution has a contact angle of preferably 30 to 90° (more preferably 40 to 80°; further preferably 45 to)70°. The contact angle is measured with water. Examples of the hydrophobic substrate include a TiN substrate, a Ru substrate and an amorphous carbon-treated substrate. Both the hydrophilic region and the hydrophobic region may be present on the substrate surface.

It is preferable that the substrate on which the substrate surface treating solution is applied has a flat surface or a stepped structure. Although not to be bound by theory, there are cases where it is difficult to partially perform the removal of the substrate cleaning solution on a substrate having a stepped structure, and it can be assumed that the substrate surface treating solution according to the present invention can be used and exhibit effects even in such cases.

### Basic Compound (A)

The basic compound (A) (hereinafter, sometimes referred to as a component (A); the same applies to (B) and the following) is not particularly limited. It may be a polymer or a low molecule compound, and is preferably a nitrogen-containing compound. In one embodiment of the present invention, the basic compound (A) is a polymer comprising a repeating unit represented by the formula (A-1) or the formula (A-2); or a compound represented by the formula (A-3) or the formula (A-4), or a saturated nitrogen-containing cyclic hydrocarbon (A-5) or a salt thereof. More preferably, the basic compound (A) is a polymer comprising a repeating unit represented by the formula (A-1) or the formula (A-2).

The basic compound (A) is, in a preferred embodiment, a nitrogen-containing polymer, more preferably a polymer comprising a repeating unit represented by the formula (A-1) or the formula (A-2).

The formula (A-1) is as follows.

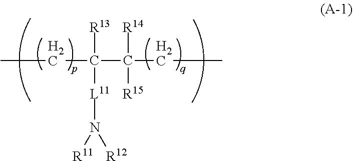

where
R¹³, R¹⁴ and R¹⁵ are each independently H, C₁₋₄ alkyl or carboxy. R¹³ and R¹⁴ are preferably H. R¹⁵ is preferably H or methyl (more preferably H).
L¹¹ is a single bond or C₁₋₄ alkylene; preferably a single bond, methylene or ethylene; more preferably a single bond or methylene; further preferably methylene.
R¹¹ is a single bond, H or C₁₋₅ alkyl; preferably a single bond, H, methyl, n-ethyl, n-propyl or n-butyl; more preferably a single bond, H or methyl. When R¹¹ is a single bond, it is bonded to R¹².
R¹² is H, C₁₋₅ alkyl, C₁₋₅ acyl or formyl; preferably H, methyl, n-ethyl, n-propyl, n-butyl, acetyl or formyl; more preferably H, methyl, n-ethyl or n-propyl; further preferably H or n-propyl.

Here, at least one of —CH₂— in the alkylene of L¹¹, the alkyl of R¹¹, and the alkyl or acyl of R¹² can be each independently replaced with —NH—. Preferably, one of —CH₂— in the alkyl or acyl of R¹² is replaced with —NH—.

An embodiment in which the replacement with —NH— does not occur is also preferred.

The single bond or alkyl of R¹¹ and the alkyl of R¹⁵ can be bonded together to form a saturated or unsaturated heterocycle. Preferably, the single bond of RI-I- and the alkyl of R¹⁵ are bonded together to form a saturated heterocycle. An embodiment that the heterocycle is not formed is also preferred.

The alkyl of R¹¹ and the alkyl, acyl or formyl of R¹² can be bonded together to form a saturated or unsaturated heterocycle. Preferably, the alkyl of R¹¹ and the alkyl of R¹² are bonded to form an unsaturated heterocycle.

The above-mentioned replacement with the —NH— can be made for —CH₂— in R¹¹ and/or R¹² used for the above-mentioned bonding. An embodiment that the heterocycle is not formed is also preferred. p and q are each independently numbers of 0 to 1; preferably 0 or 1; more preferably 0.

Examples of the polymer comprising the repeating unit represented by the formula (A-1) include polyallylamine, polydiallylamine, polyvinylpyrrolidone, polyvinylimidazole, polyvinylamine and copolymers of any of these, and polyallylamine and polydiallylamine are preferable.

The repeating unit of polydiallylamine is explained particularly by the formula (A-1). p=q=1. R¹², R¹³ and R¹⁴ are H. L¹¹ is methylene and R¹⁵ is methyl. R¹¹ is a single bond and bonded to R¹⁵ to form a saturated heterocycle.

The formula (A-2) is as follows.

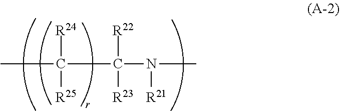

where
R²¹ is each independently H, a single bond, C₁₋₄ alkyl or carboxy (—COOH); preferably H, a single bond or methyl; more preferably H or a single bond; further preferably H. The single bond of R²¹ may be bonded to another repeating unit, and the single bond not used at the end of the polymer may be bonded with H or the like.
R²², R²³, R²⁴ and R²⁵ are each independently H, C₁₋₄ alkyl or carboxy; preferably H or methyl; more preferably H.
r is a number of 0 to 3; preferably 0 or 1; more preferably 1.

Examples of the polymer comprising the repeating unit represented by the formula (A-2) include polyethyleneimine. Polyethyleneimine may be linear or branched.

The linear polyethyleneimine is explained particularly by the formula (A-2). r=1, and R²¹, R²², R²³, R²⁴ and R²⁵ are H.

The branched polyethyleneimine is explained particularly by the formula (A-2). r=1, and R²¹ is H or a single bond. R²², R²³, R²⁴ and R²⁵ are H.

The nitrogen-containing polymer can also contain a repeating unit other than the repeating units represented by the formulas (A-1) and (A-2). Although there is no intention to limit the present invention, examples of such a unit include CH₂CHCOOH, CH₂CHCH₂NH₂, CH₂CHCH₂NHCOOCH₃, SO₂, CH₂CHCH₂NHCOCH₃, CH₂CHCH₂NHCH₂COOH or CHCOOH. The repeating unit other than the repeating units represented by the formulas (A-1) and (A-2) is preferably 50 mol % or less; more preferably 30 mol % or less; further preferably 5 mol % or less, based on the total repeating units constituting the polymer. It is also a preferred embodiment of the present invention that these are not contained (0%).

The nitrogen-containing polymer may be added to the substrate surface treating solution as a salt (for example, hydrochloride, acetate, sulfate, phosphate).

When the basic compound (A) is a low molecule compound, it is preferably a compound represented by the formula (A-3) or the formula (A-4), or a saturated nitrogen-containing cyclic hydrocarbon (A-5) or a salt thereof.

The formula (A-3) is as follows.

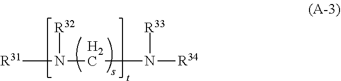

where
R³¹, R³², R³³ and R³⁴ are each independently H or methyl.
s is a number of 2 to 5; preferably an integer of 2 to 4; more preferably 2 or 3.
t is a number of 1 to 5; preferably an integer of 1 to 3; more preferably 1 or 2. When t is 2 to 5, the constituent enclosed in parentheses to which t is attached may be identical or different.

Examples of the compound represented by the formula (A-3) include 1,4-diaminobutane, N,N′-bis (3-aminopropyl)ethylenediamine, N,N,N′,N″,N″-pentamethylethylenediamine, N,N,N′,N′-tetramethylethylenediamine, 2,6,10-trimethyl-2,6,10-triazaundecan, N,N,N′,N′-tetramethyl-1,3-diaminopropane and 1,1,4,7,10,10-hexamethyltriethylenetetramine.

The formula (A-4) is as follows.

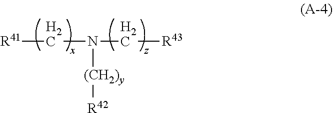

where
R⁴¹ is H, hydroxy or vinyl; preferably H or vinyl more preferably vinyl.
R⁴² is H, hydroxy, vinyl, amino (—NH₂) or phenyl; preferably hydroxy, vinyl, amino or phenyl; more preferably hydroxy, vinyl or amino; further preferably hydroxy or vinyl.
R⁴³ is H, hydroxy or vinyl; preferably H or hydroxy; more preferably H.
x is a number of 1 to 5; preferably an integer of 1 to 4; more preferably 1 or 2.
y is a number of 1 to 5; preferably an integer of 1 to 4; more preferably 1 to 3.
z is a number of 0 to 5; preferably an integer of 0 to 4; more preferably 0 or 1.

Examples of the compound represented by the formula (A-4) include diallylamine, triallylamine, 2-(2-aminoethylamino)ethanol, diethanolamine, 2-(butylamino)ethanol and N-benzylethanolamine.

The saturated nitrogen-containing cyclic hydrocarbon (A-5) is preferably a saturated ring having —N—CH₂—, —N—CH₂—CH₂— or —NH—CH₂—CH₂— as a constituent unit. It is a preferable embodiment that by repeatedly having one kind of constitutional unit, a ring structure is made. The saturated nitrogen-containing cyclic hydrocarbon (A-5) may have a cage-shaped three-dimensional structure or a planar ring structure. Although there is no intention to limit the present invention, exemplified embodiments of (A-5) which has a cage-shaped three-dimensional structure include 1,4-diazabicyclo[2.2.2]octane and hexamethylene-tetramine, and exemplified embodiments of (A-5) which has a planar ring structure include 1,4,7,10-tetra-azacyclododecane and 1,4,7,10,13,16-hexaazacyclo-octadecane.

When the basic compound (A) is a polymer, the mass average molecular weight (Mw) is preferably 100 to 100,000; more preferably 100 to 10,000; further preferably 100 to 5,000. Here, in the present invention, Mw means a Mw in terms of polystyrene, which is measured by the gel permeation chromatography based on polystyrene. The same applies to the following.

When the basic compound (A) is a low molecule compound, the molecular weight is preferably 20 to 5,000; more preferably 30 to 1,000; further preferably 40 to 500.

The content of the basic compound (A) is preferably 0.001 to 99.9 mass %; more preferably 0.001 to 50 mass %; further preferably 0.001 to 10 mass %; further more preferably 0.005 to 5 mass %, based on the total mass of the substrate surface treating solution.

### Solvent (B)

The substrate surface treating solution according to the present invention comprises a solvent (B).

In a preferred embodiment of the substrate surface treating solution of the present invention, the solvent (B) comprises water (B-1), and in a more preferable embodiment, the content of water (B-1) is 50 to 100 mass %; preferably 90 to 100 mass %; more preferably 95 to 100 mass %, based on the solvent (B). It is also a preferred embodiment that any solvent other than water (B-1) is not contained (100 mass %). The water (B-1) is preferably deionized water (DIW). Preferably, the solvent (B) does not contain a polymer comprising a repeating unit represented by the formula (A-1) or the formula (A-2), or a compound represented by the formula (A-3) or the formula (A-4), or a saturated nitrogen-containing cyclic hydrocarbon (A-5) or a salt thereof.

The solvent (B) can also contain an organic solvent (B-2). Examples of the organic solvent (B-2) include alcohols such as ethanol (EtOH) and isopropanol (IPA); ethylene glycol monoalkyl ethers such as ethylene glycol monomethyl ether and ethylene glycol monoethyl ether; ethylene glycol monoalkyl ether acetates such as ethylene glycol monomethyl ether acetate and ethylene glycol monoethyl ether acetate; propylene glycol monoalkyl ethers such as propylene glycol monomethyl ether (PGME), propylene glycol monoethyl ether (PGEE); propylene glycol monoalkyl ether acetates such as propylene glycol monomethyl ether acetate (PGMEA), propylene glycol monoethyl ether acetate; lactates such as methyl lactate and ethyl lactate (EL); aromatic hydrocarbons such as toluene and xylene; ketones such as methyl ethyl ketone, 2-heptanone and cyclohexanone; amides such as N,N-dimethylacetamide and N-methylpyrrolidone; and lactones such as γ-butyrolactone. These organic solvents can be used alone or as a mixture of any two or more of these.

Exemplified embodiments of the organic solvent (B-2) include preferably EtOH, IPA, PGME, PGEE, PGMEA or a mixture of any of these (more preferably EtOH, IPA, PGME, PGEE or a mixture of any of these; further preferably EtOH, IPA, PGME, PGEE or a mixture of any of these; further more preferably EtOH, IPA, PGME or PGEE).

In one embodiment of the present invention, the solvent (B) preferably substantially consists of water (B-1) and the organic solvent (B-2); more preferably consists only of water (B-1) and the organic solvent (B). In another embodiment of the present invention, the solvent (B) preferably substantially consists of the organic solvent (B-2); more preferably consists only of the organic solvent (B-2).

The content of the solvent (B) is preferably 0.001 to 99.999 mass %; more preferably 50 to 99.99 mass %; further preferably 90 to 99.99 mass %; further more preferably 95 to 99.995 mass %, based on the total mass of the substrate surface treating solution.

### Surfactant (C)

The substrate surface treating solution according to the present invention can further contain a surfactant (C). The surfactant (C) is useful for improving coatability or solubility. Examples of the surfactant that can be used in the present invention include (I) anionic surfactant, (II) cationic surfactant, or (III) nonionic surfactant, and more particularly, (I) alkyl sulfonate, alkyl benzene sulfonic acid and alkyl benzene sulfonate, (ii) lauryl pyridinium chloride and lauryl methyl ammonium chloride, and (iii) polyoxyethylene octyl ether, polyoxyethylene lauryl ether, polyoxyethylene acetylenic glycol ether, fluorine-containing surfactants (for example, Fluorad (3M), Megafac (DIC), SurfIon (AGC Seimi Chemical) and organic siloxane surfactants (for example, KF-53, KP341 (Shinetsu Chemical Industry)).

These surfactants can be used alone or in combination of two or more of these.

The content of the surfactant (C) is preferably 0.001 to 5 mass %; more preferably 0.001 to 1 mass %; further preferably 0.001 to 0.1 mass %, based on the total mass of the substrate surface treating solution. It is also one embodiment of the present invention that any surfactant (C) is not contained (0 mass %).

### Moisturizing Agent (D)

The substrate surface treating solution according to the present invention can further contain a moisturizing agent (D). Although not to be bound by theory, it is assumed that the moisturizing agent (D) is useful for clathrating the solvent (B) in the formed substrate surface treatment layer and improving the substrate surface modification performance. Although not to be bound by theory, it is assumed that the inclusion of the moisturizing agent (D) makes it easier to hold the solvent (B) in the substrate surface treatment layer without being completely removed from on the substrate.

As the moisturizing agent (D), glycols are preferable, and examples thereof include ethylene glycol, diethylene glycol, triethylene glycol, tetraethylene glycol, pentaethylene glycol and polyethylene glycol.

The content of the moisturizing agent (D) is preferably 0.001 to 10 mass %; more preferably 0.001 to 5 mass %; further preferably 0.01 to 5 mass %, based on the total mass of the substrate surface treating solution. It is also one embodiment of the present invention that any moisturizing agent (D) is not contained (0 mass %).

### Further Additives (E)

The substrate surface treating solution of the present invention can further contain a further additive (E). The further additive (E) comprises an acid, a base (excluding the basic compound (A)), an antibacterial agent, a bactericide, a preservative and an antifungal agent, and it can comprise any combination of any of these.

The content of the further additive (E) (in the case of a plurality thereof, the sum thereof) is preferably 0 to 10 mass %; more preferably 0.001 to 5 mass %; further preferably 0.001 to 3 mass %; further more preferably 0.001 to 1 mass %, based on the total mass of the substrate surface treating solution. It is also one embodiment of the present invention that the substrate surface treating solution does not contain any further additives (E) (0 mass %).

### Substrate Cleaning Solution

The substrate surface treating solution used in the present invention forms a substrate surface treatment layer, on which the substrate cleaning solution is applied. The substrate cleaning solution is not particularly limited as long as it is one used for substrate cleaning, but preferably comprises an insoluble or hardly soluble solute (a), a soluble solute (b) and a solvent (c). Hereinafter, for the simplicity, they are sometimes referred to as a component (a), a component (b) and a component (c), respectively.

Here, preferably the component (a) is insoluble or hardly soluble in a remover. Further, preferably the component (b) is soluble in a remover.

Here, preferably the solubility of the component (a) in 5.0 mass % ammonia water is less than 100 ppm, and the solubility of the component (b) in 5.0 mass % ammonia water is 100 ppm or more.

In the present invention, the “solute” is not limited to the state of being dissolved in the solvent (c), and a suspended state thereof is also accepted. In a preferred embodiment of the present invention, the solutes, components and additives contained in the substrate cleaning solution are soluble in the solvent (c). The substrate cleaning solution in this embodiment is assumed to have good embedding properties or film uniformity.

The substrate cleaning solution used in the present invention is preferably dripped on a substrate and dried to remove at least a part of the solvent (c) to form a substrate cleaning film, and the substrate cleaning film is then removed from on the substrate with a remover.

“to form a substrate cleaning film” means to form one film and to be in a state of coexistence in one film. One embodiment of the substrate cleaning film formation is “ solidification ” of a solute. It is enough that the substrate cleaning film has a hardness to the extent to hold particles, and the solvent (c) is not completely removed (for example, through vaporization). The substrate cleaning solution becomes a substrate cleaning film while gradually shrinking as the solvent (c) vaporizes. It is accepted that an extremely small amount of the component (a) and the component (b) is removed (for example, vaporization, volatilization). For example, it is accepted that 0 to 10 mass % (preferably 0 to 5 mass %; more preferably 0 to 3 mass %; further preferably 0 to 1 mass %; further more preferably 0 to 0.5 mass %) based on the original amount is removed.

Although not to be bound by theory, it is assumed that particles are held in the substrate cleaning film on the substrate and the film is peeled off by a remover (1), thereby removing particles. It is assumed that the component (b) in the film generates a portion which becomes a trigger that the film peels.

### Insoluble or Hardly Soluble Solute (a)

The component (a) comprises at least one of novolak derivatives, phenol derivatives, polystyrene derivatives, polyacrylate derivatives, polymaleic acid derivatives, polycarbonate derivatives, polyvinyl alcohol derivatives, polymethacrylate derivatives, and copolymer of any combination of any of these.

Novolak derivatives preferably comprise the following repeating unit.

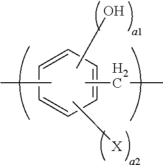

wherein
X is each independently C₁₋₂₇ substituted or unsubstituted hydrocarbon group. X is preferably methyl or t-butyl; more preferably methyl.
a1 is 1 to 2; preferably 1.
a2 is 0 to 3, preferably 0 or 1; more preferably 1.

Exemplified examples of the repeating unit of novolak derivatives are the following.

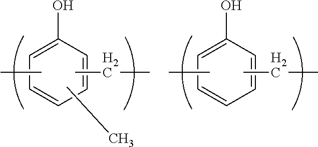

Phenol derivatives are not particularly limited, but preferably have a molecular weight of 150 or more and are solid at normal temperature (20° C.). More particular embodiments of phenol derivatives include compounds represented by the following formula and polymer thereof.

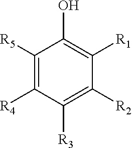

wherein
R₁ to R₅ are each independently hydrogen, C₁₋₆ alkyl (preferably methyl, ethyl, isopropyl or n-propyl), hydroxy, phenyl, benzyl, aldehyde, amino, nitro, or sulfo.

More particularly, phenol derivatives include the following structures.

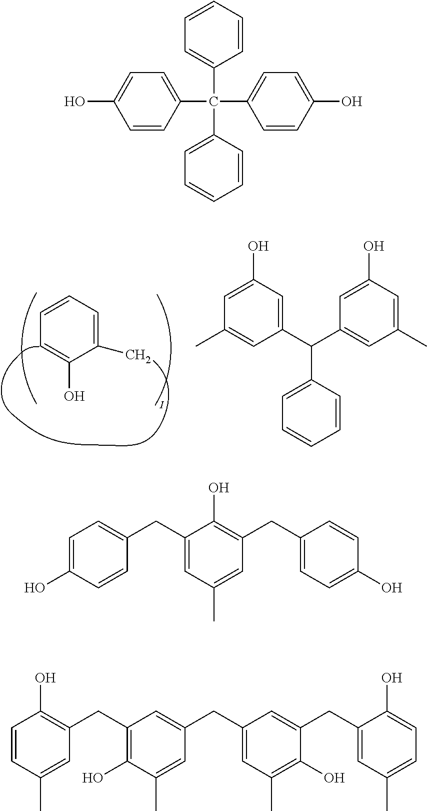

Polystyrene derivatives may be polyhydroxystyrene derivatives; preferably polyhydroxystyrene derivatives. Examples of polystyrene derivatives include those having structures represented by the following formulae.

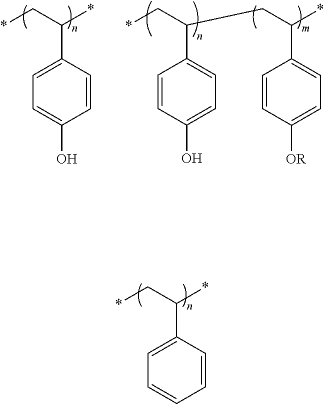

wherein
R is hydrogen, C₁₋₆ alkyl (preferably methyl, ethyl, isopropyl or n-propyl), phenyl, benzyl, aldehyde, amino or nitro.

Examples of polyacrylate derivatives include one having a structure represented by the following formula.

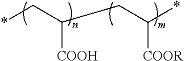

wherein
R is C₁₋₆ alkyl (preferably methyl, ethyl, isopropyl or n- propyl), phenyl, benzyl, aldehyde, amino or nitro.

Examples of polymaleic acid derivatives include one having a structure represented by the following formula.

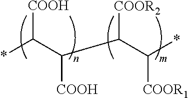

wherein
R₁ and R₂ are each independently C₁₋₆ alkyl (preferably methyl, ethyl, isopropyl or n-propyl), phenyl, benzyl, aldehyde, amino or nitro.

Examples of polycarbonate derivatives include one represented by the following formula.

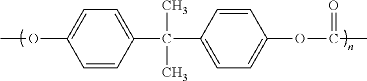

Examples of polyvinyl alcohol derivatives include one represented by the following formula.

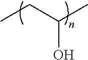

Examples of polymethacrylate derivatives include one represented by the following formula, and more preferably polymethylmethacrylate.

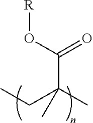

wherein
R is C₁₋₆ alkyl (preferably methyl, ethyl, isopropyl or n-propyl), phenyl, benzyl, aldehyde, amino or nitro.

The component (a) comprises preferably at least one of novolak derivatives, phenol derivatives, polyhydroxystyrene derivatives, polyacrylate derivatives, polycarbonate derivatives, polymethacrylate derivatives, and copolymer of any combination of any of these; more preferably at least one of novolak derivatives, phenol derivatives, polyhydroxystyrene derivatives, and copolymer of any combination of any of these; further preferably at least one of novolak derivatives, phenol derivatives, and polyhydroxystyrene derivatives; and further more preferably novolak derivatives.

The copolymer is preferably a random copolymer or a block copolymer.

The substrate cleaning solution according to the present invention may comprise one or more of the above-mentioned preferred examples in combination as the component (a). For example, the component (a) may contain both novolak derivatives and polyhydroxystyrene derivatives.

The molecular weight (M_{w} in the case of a polymer) of the component (a) is preferably 150 to 500,000; more preferably 300 to 300,000; further preferably 500 to 100,000; further more preferably 1,000 to 50,000.

The component (a) can be obtained through synthesis thereof. It is also possible to purchase it. When purchasing, examples of the supplier are indicated below.
novolak: Showa Kasei, Asahi Yukizai, Gunei Chemical Industry, Sumitomo Bakelite
polyhydroxystyrene: Nippon Soda, Maruzen Petrochemical, Toho Chemical Industry
polyacrylic acid derivatives: Nippon Shokubai polycarbonate: Sigma-Aldrich
polymethacrylic acid derivatives: Sigma-Aldrich

The content of the component (a) is 0.1 to 50 mass %; preferably 0.5 to 30 mass %; more preferably 1 to 20 mass %; further preferably 1 to 10 mass %; further more preferably 2 to 7 mass %0, based on the substrate cleaning solution.

The solubility can be evaluated by known methods. For example, it can be obtained under the condition of 20 to 35° C. (more preferably 25±2° C.) by adding 100 ppm of the component (a) or the component (b) into 5.0 mass % ammonia water in a flask, covering the flask with a cap, shaking for 3 hours in a shaker, and confirming whether the component (a) or the component (b) is dissolved or not. The shaking may be stirring. Dissolution can be also judged visually. If it is not dissolved, the solubility is determined to be less than 100 ppm, and if it is dissolved, the solubility is determined to be 100 ppm or more. In the present specification, the solubility of less than 100 ppm is determined to be insoluble or hardly soluble, and the solubility of 100 ppm or more is determined to be soluble. In the present specification, soluble includes slightly soluble in a broad sense. In the present specification, the solubility becomes higher in the order of insoluble, hardly soluble and soluble. In the present specification, slightly soluble is less soluble than soluble and more soluble than hardly soluble in a narrow sense.

Preferably, the solubility of the component (a) in 5.0 mass % ammonia water is less than 100 ppm, and the solubility of the component (b) in 5.0 mass % ammonia water is 100 ppm or more.

The above-mentioned 5.0 mass % ammonia water may be changed to a remover (1) (described later) that is used in a later process. A preferred embodiment of the present invention includes an embodiment in which the component (b) present in the film formed from the substrate cleaning solution is dissolved by the remover (1) to give a trigger that the film peels. Therefore, it is assumed that if a part of the component (b) can be dissolved by the remover (1), the substrate cleaning film can be removed. For that reason, it is assumed good, for example, even if the remover (1) is weaker in alkalinity than the liquid used in the solubility evaluation.

### Soluble Solute (b)

The component (b) is preferably a compound comprising carboxy, sulfo or phospho; more preferably a compound comprising carboxy or phospho; further preferably a compound comprising carboxy.

The acid dissociation constant pKa (H₂O) of the component (b) is preferably −5 to 11 (more preferably −1 to 8; further preferably 1 to 7; further more preferably 2 to 6.

The component (b) is preferably a crack accelerating component (b′), where the crack accelerating component (b′) preferably comprises hydrocarbon containing carboxy.

Although not to be bound by theory, it is assumed that when the remover (1) peels off the substrate cleaning film, the component (b) generates a portion to become a trigger that the film peels. For this purpose, it is preferable that the component (b) has a higher solubility in the remover than the component (a).

Preferably, the component (b) comprises a structural unit represented by the formula (B-1).

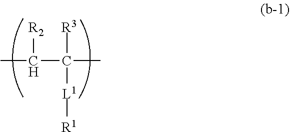

wherein
L¹ is a single bond, C₁₋₄ alkylene, phenylene, ether, carbonyl, amide or imide; preferably a single bond, methylene, ethylene, phenylene or amide; more preferably a single bond or phenylene; further more preferably a single bond. When L¹ is amide or imide, the H present in the amide or the imide may be substituted with methyl, and preferably not be substituted.
R¹ is carboxy, sulfo or phospho; preferably carboxy or sulfo; more preferably carboxy.
R² is hydrogen, methyl or carboxy; preferably hydrogen or carboxy; more preferably hydrogen.
R³ is hydrogen or methyl; preferably hydrogen.

Preferably, the component (b) is a polymer comprising a repeating unit represented by the formula (b-1). Preferred examples of the polymer comprising the repeating unit represented by the formula (b-1) include polyacrylic acid, polymaleic acid, polystyrenesulfonic acid, or a polymer of any combination of any of these. Polyacrylic acid and copolymer of maleic acid and acrylic acid are further preferred examples.

In the case of copolymerization, it is preferably random copolymerization or block copolymerization; more preferably random copolymerization.

Copolymer of maleic acid and acrylic acid is given as an example for explanation. The copolymer is contained in (b-1) and has two types of structural units represented by (b-1).

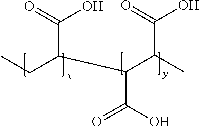

The molecular weight of the component (b) (M_{w} in the case of a polymer) is preferably 500 to 500,000; more preferably 1,000 to 100,000; further preferably 2,000 to 50,000; further more preferably 5,000 to 50,000; further more preferably 5,000 to 40,000.

The component (b) can be obtained even by either synthesizing or purchasing. As the supplier, Sigma-Aldrich, Tokyo Chemical Industry and Nippon Shokubai are mentioned.

The content of the component (b) is preferably 1 to 100 mass %; more preferably 1 to 50 mass %; further preferably 1 to 30 mass %; further more preferably 1 to 10 mass %, based on the total mass of the component (a).

### Solvent (c)

The solvent (c) preferably comprises water (c-1). The content of the component (b) is preferably 0.1 to 500 mass % (more preferably 0.1 to 100 mass %; further preferably 0.5 to 50 mass %; further more preferably 0.5 to 10 mass %) based on water (c-1). Water (c-1) is preferably deionized water.

The content of water (c-1) is preferably 0.01 to 50 mass % (more preferably 0.01 to 20 mass %; further preferably 0.05 to 20 mass %) based on the solvent (c).

The solvent (c) can contain an organic solvent (c-2).

Preferably, the organic solvent (c-2) has volatility. In the present invention, having volatility means to have higher volatility compared with water. For example, the boiling point of the solvent (c-2) at one atmospheric pressure is preferably 50 to 250° C.; more preferably 50 to 200° C.; further preferably 60 to 170° C.; further more preferably 70 to 150° C.

The organic solvent (c-2) includes alcohols such as IPA; ethylene glycol monoalkyl ethers such as ethylene glycol monomethyl ether and ethylene glycol monoethyl ether; ethylene glycol mono alkyl ether acetates such as ethylene glycol monomethyl ether acetate and ethylene glycol monoethyl ether acetate; propylene glycol monoalkyl ethers such as PGME and PGEE; propylene glycol monoalkyl ether acetates such as PGMEA and propylene glycol monoethyl ether acetate; lactic acid esters such as methyl lactate and EL; aromatic hydrocarbons such as toluene and xylene; ketones such as methyl ethyl ketone, 2-heptanone and cyclohexanone; amides such as N,N-dimethylacetamide and N-methyl pyrrolidone; and lactones such as γ-butyrolactone. These organic solvents can be used alone or in any combination of any two or more of these.

In a preferred embodiment, the organic solvent (c-2) is selected from IPA, PGME, PGEE, EL, PGMEA, and any combination of any of these. When the organic solvent is a combination of two types, the volume ratio is preferably 20:80 to 80:20; more preferably 30:70 to 70:30.

The solubility of the organic solvent (c-2) in water is preferably 10 g/100 g H₂O or more; more preferably 20 g/100 g H₂O or more; further preferably 25 to 1,000 g/100 g H₂O; further more preferably 50 to 200 g/100 g H₂O. The measurement of the solubility in water is preferably conducted at normal temperature and normal pressure, where the normal temperature is 20 to 30° C. (preferably 22 to 28° C.) and the normal pressure is preferably the standard atmospheric pressure or ±15% range around the standard atmospheric pressure.

In one embodiment of the present invention, the content of the solvent (c) is 0.1 to 99.9 mass % (preferably 50 to 99.9 mass %; more preferably 75 to 99.5 mass %; further preferably 80 to 99 mass %; further more preferably 90 to 99 mass %) based on the substrate cleaning solution.

### Alkaline Component (d)

The substrate cleaning solution used in the present invention can further contain an alkaline component (d). Although not to be bound by theory, it is assumed that the alkaline component (d) remains in the substrate cleaning film and when the remover (1) removes the film, the alkaline component (d) dissolves into the remover (1), which can give a trigger that the film peels. The boiling point of the alkaline component (d) at 1 atm is preferably 20 to 400° C.; more preferably 115 to 350° C.; further preferably 200 to 350° C.

Although there is no intention to limit the present invention, exemplified embodiments of the alkaline component (d) include N-benzylethanolamine, diethanolamine, monoethanolamine, 2-(2-aminoethyl-amino)ethanol, 4,4′-diaminodiphenylmethane, 2-(butyl-amino)ethanol, 2-anilinoethanol, triethanolamine, ethylenediamine, diethylenetriamine, tris(2-aminoethyl)-amine, tris[2-(dimethylamino)ethyl]amine, N,N,N′,N′-tetrakis(2-hydroxyethyl)ethylenediamine, N,N,N′,N′-tetraethylethylenediamine, 1,4-diazabicyclo[2.2.2]-octane, hexamethylenetetramine, 1,4,7,10-tetraaza-cyclododecane and 1 4,7,10,13,16-hexaaza-cyclooctadecane.

The molecular weight of the alkaline component (d) is preferably 50 to 500; more preferably 80 to 300. The alkaline component (d) can be obtained even by either synthesizing or purchasing. As the supplier, Sigma-Aldrich and Tokyo Chemical Industry are mentioned.

The alkaline component (d) is preferably 1 to 100 mass % (more preferably 1 to 50 mass %; further preferably 1 to 30 mass %) as compared with the sum of the masses of the component (a) and the component (b) in the substrate cleaning solution.

### Further Additive (e)

The substrate cleaning solution used in the present invention may further contain a further additive (e) other than the components (a) to (d). Here, the further additive (e) comprises a surfactant, an acid, an antibacterial agent, a bactericide, a preservative or an antifungal agent, and it may comprise any combination of any of these. The further additive (e) preferably comprises a surfactant.

In one embodiment of the present invention, the content of the further additive (e) (in the case of plural, the sum thereof) is 0 to 100 mass % (preferably 0 to 10 mass %; more preferably 0 to 5 mass %; further preferably 0 to 3 mass %; further more preferably 0 to 1 mass %) based on the component (a). It is also one of the embodiments of the present invention that the substrate cleaning solution contains no further additive (e) (0 mass %).

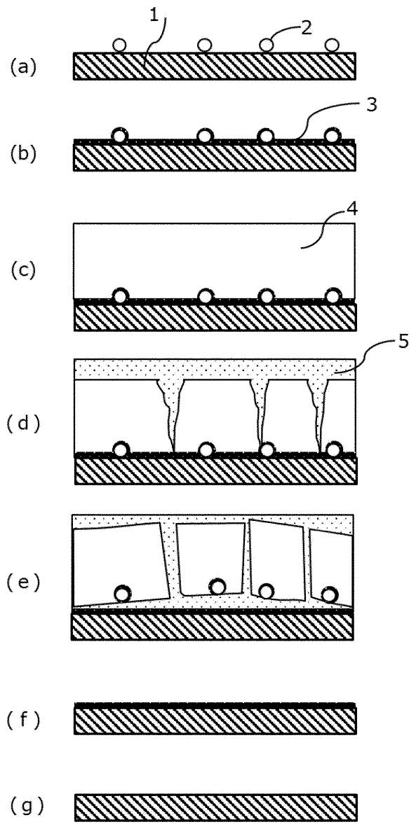

Although there is no intention to limit the present invention and this is not to be bound by theory, one embodiment of the method for manufacturing a cleaned substrate using the substrate surface treating solution according to the present invention is described using a schematic drawing (FIG. 1) for the understanding of the present invention.

FIG. 1(a) shows a state in which particles 2 are attached to the substrate 1. FIG. 1(b) shows a state in which the substrate surface treating solution according to the present invention is applied on the substrate to form a substrate surface treatment layer 3. FIG. 1(c) shows a state in which the substrate cleaning solution is applied on this and a substrate cleaning film 4 is formed. FIG. 1(d) shows a state in which particles are held in the substrate cleaning film and the remover (1) 5 is applied thereon. FIG. 1(e) shows a state in which the substrate cleaning film is removed from the substrate while holding particles, and FIG. 1(f) shows a state in which the substrate cleaning film is removed. The remover (2) is applied on this, and a cleaned substrate is obtained. This state is shown by FIG. 1(g).

### Method for Manufacturing a Cleaned Substrate

The method for manufacturing a cleaned substrate according to the present invention comprises the following steps:
(1) applying the substrate surface treating solution according to the present invention on a substrate;
(2) forming a substrate surface treatment layer containing at least a part of a basic compound (A) from the substrate surface treating solution;
(3) applying a substrate cleaning solution on the substrate surface treatment layer;
(4) forming a substrate cleaning film from the substrate cleaning solution;
(5) removing the substrate cleaning film with a remover (1); and
(6) removing the substrate surface treatment layer with a remover (2).

Hereinafter, the method for cleaning a substrate is described using a more particular embodiment.

Hereinafter, the numbers in parentheses indicate the order of the steps. For example, when the steps (0-1), (0-2) and (1) are described, the order of the steps is as described above.

### Step (1)

In the step 1, the substrate surface treating solution according to the present invention is applied on a substrate.

The substrate to be cleaned in the present invention include semiconductor wafers, glass substrates for liquid crystal display, glass substrates for organic EL display, glass substrates for plasma display, substrates for optical disk, substrates for magnetic disk, substrates for magneto-optical disk, glass substrates for photomask, substrates for solar cell, and the like. The substrate may be a non-processed substrate (for example, a bare wafer) or a processed substrate (for example, a patterned substrate). The substrate may be composed by laminating a plurality of layers. Preferably, the substrate surface is a semiconductor. The semiconductor may be composed of oxide, nitride, metal, and any combination of any of these.

The substrate surface may be hydrophilic or hydrophobic. When it is hydrophobic, the effect of he present invention can be more exhibited, which is preferable. Examples of the hydrophobic substrate include a TiN substrate, a Ru substrate and an amorphous carbon-treated substrate.

The shape of the substrate is preferably a disk-shaped substrate having a diameter of 150 to 600 mm (more preferably 200 to 400 mm).

Even when it is a hydrophilic substrate, the substrate surface treatment layer of the present invention is formed, and it is possible to perform subsequent removal of particles by the substrate cleaning film. Although not to be bound by theory, since a plurality of processing are performed on a substrate to be actually manufactured, a hydrophobic region and a hydrophilic region may both exist on the substrate surface at the stage of cleaning the substrate, utilizing the substrate surface treating solution is assumed effective. For example, on the surface of the hydrophilic substrate, the regions where the silicon oxide film has been scraped by etching sometimes loses its hydrophilicity.

The method for applying the substrate surface treating solution is not particularly limited, but it is preferably conducted by dripping the substrate surface treating solution nearly at the center of the horizontally postured substrate through a nozzle or the like in an apparatus suitable for substrate cleaning. The dripping may be in the form of liquid column or dropping. At the time of the dripping, the substrate is rotated, for example, at 10 to several tens of rpm, so that the generation of dripping traces can be suppressed. The dripping amount can be adjusted depending on the size and shape of the substrate, but is preferably 10 to 500 cc (more preferably 10 to 300 cc).

### Step (2)

In the step (2), a substrate surface treatment layer containing at least a part of the basic compound (A) is formed from the substrate surface treating solution. For example, it is also a preferred embodiment that the basic compound (A) remains on the substrate as a thin film and other components are removed. A part of the components other than the solvent (B) may be solidified to form a substrate surface treatment layer and remain on the substrate. When the basic compound (A) is a liquid at the normal temperature and pressure, it may remain on the substrate in, a liquid state.

At least a part of the solvent (C) is removed from the substrate surface treating solution applied on the substrate by rotating the substrate, applying a rinse, heating on a hot plate, or a combination thereof, thereby forming the substrate surface treatment layer containing at least a part of the basic compound (A). In one preferred embodiment of the present invention, in the step (2), the substrate is rotated to shake off the excess substrate surface treating solution, and a rinse (more preferably an aqueous rinse) is applied. Although not to be bound by theory, it is assumed that addition of the application of a rinse makes it possible to perform the removal with remaining a thin film of the substrate surface treatment layer that is in contact with the substrate surface and it becomes possible to form a substrate surface treatment layer that is along the surface shape of the processed substrate (for example, having a stepped structure). It is one preferred embodiment that the substrate surface treatment layer to be formed has a film thickness of 0.001 nm to 2 nm. In addition, although not to be bound by theory, it is assumed that when application of a rinse is added, the substrate surface treatment layer becomes sufficiently thin and thereby the substrate surface treatment layer can grab particles, which makes more effective removal of particles possible.

It is also a preferred embodiment of the present invention that the substrate surface treatment layer is formed by rotating the substrate. This rotation is preferably performed at 500 to 3,000 rpm (more preferably 1,000 to 2,000 rpm) for 0.5 to 90 seconds (more preferably 5 to 80 seconds; further preferably 15 to 70 seconds).

### Step (3)

In the step (3), the substrate cleaning solution is applied on the substrate surface treatment layer. The method for applying the substrate cleaning solution can be conducted in the same manner as the application of the substrate surface treating solution in the step (1). The dripping amount of the substrate cleaning solution is preferably 0.5 to 10 cc. These conditions can be adjusted so that the substrate cleaning solution is uniformly coated and spread.

### Step (4)

In the step (4), a substrate cleaning film is formed from the substrate cleaning solution. At least a part of the solvent of the substrate cleaning solution is removed, and at least a part of the solid component of the substrate cleaning solution forms a substrate cleaning film. The film formation is conducted by heating, rotation of the substrate or the like; preferably by rotation of the substrate. The rotation of the substrate is preferably performed at 500 to 3,000 rpm (more preferably 500 to 1,500 rpm; further preferably 500 to 1,000 rpm) and preferably for 0.5 to 90 seconds (more preferably 5 to 80 seconds; further preferably 15 to 70 seconds; further more preferably 30 to 60 seconds).

This makes it possible to remove at least a part of the solvent contained in the substrate cleaning solution while spreading the substrate cleaning solution over the entire surface of the substrate. The above-mentioned heating can be achieved also by raising the temperature in the apparatus. It can be expected that raising of the temperature promotes the film formation of the solid components in the substrate cleaning solution. When the temperature is raised, it is preferably 40 to 150° C.

### Step (5)

In the step (5), the substrate cleaning film is removed by the remover (1).

The substrate cleaning film can hold particles existing on the substrate, and it is one preferred embodiment of the present invention that the particles are removed by the remover (1) while being held.

The remover (1) may be alkaline, neutral or acidic, but is preferably neutral. In one embodiment of the present invention, the pH of the remover (1) is 6 to 8 (preferably 6.5 to 7.5; more preferably 6.8 to 7.2; further preferably 6.9 to 7.1). A more particular embodiment of the neutral remover is DIW.

In another embodiment of the present invention, it is possible that the remover (1) is alkaline. The pH of the alkaline remover is 7 to 13 (preferably 8 to 13; more preferably 11 to 12.5).

It is preferable to measure the pH by degassing in order to avoid the influence of the dissolution of carbon dioxide in the air.

Application of the remover (1) can be performed, for example, by dripping, spraying or immersion. The dripping may be performed so as to form a liquid pool (paddle) on the substrate, or it may be continuously performed. In one embodiment of the present invention, the remover (1) is dripped on the center of the substrate while the substrate is rotated at 500 to 800 rpm.

It is a preferred embodiment of the present invention that the substrate cleaning film is removed from the substrate while holding particles without being completely dissolved by the remover (1).

### Step (6)

In the step (6), the substrate surface treatment layer is removed by the remover (2).

The remover (2) is not particularly limited as long as it dissolves the substrate surface treatment layer, but is preferably acidic. In one embodiment of the present invention, the pH of the remover (2) is preferably 1 to 6 (more preferably 1 to 3).

Although there is no intention to limit the present invention, exemplified embodiments of the remover (2) include hydrochloric acid aqueous solution, dilute sulfuric acid aqueous solution, acetic acid aqueous solution, nitric acid aqueous solution, and any combination of any of these; more preferably hydrochloric acid aqueous solution.

The acid component is preferably 0.1 to 10 mass % (more preferably 0.1 to 5 mass %; further preferably 0.5 to 2 mass %) based on the total mass of the remover (2). The main component of the remover (2) is preferably water or the solvent (B); more preferably water. Although not to be bound by theory, it is desirable that the substrate surface is not damaged and the chemical and electrical properties of the substrate surface are not changed while removing the substrate surface treatment layer.

The remover (2) can be applied in he same manner as the application method of the remover (1).

For the method for cleaning a substrate according to the present invention, an embodiment that at least one step other than the above-mentioned is further contained is also preferable. Such steps include those known for the cleaning of a substrate. For example, the following steps are mentioned.
(0-1) processing a pattern on the substrate by etching, and removing the etching mask;
(0-2) cleaning the substrate;
(0-3) prewetting the substrate;
(0-4) cleaning the substrate; and
(7) further cleaning the substrate by dripping water or an organic solvent on the substrate from which the substrate surface treatment layer has been removed and by removing the water or the organic solvent.

### Step (0-1)

In the step (0-1), a pattern is processed on the substrate by etching, and the etching mask is removed. The substrate to be cleaned may be a processed substrate, and the processing may be performed by a lithography technique.

### Step (0-2)

In the step (0-2), a substrate is cleaned with a known cleaning solution (rinse or the like) in order to reduce the number of particles on the substrate. It is one of the objects of the present invention to remove a few particles remaining even by this.

### Step (0-3)

In the step (0-3), the substrate is subjected to prewetting. It is also a preferred embodiment to include this step in order to improve the coatability of the substrate surface treating solution of the present invention for spreading it uniformly on the substrate. As the liquid (prewetting liquid) preferably used for prewetting, IPA, PGME, PGMEA, PGEE, n-butanol (nBA), pure water, and any combination of any of these are mentioned.

### Step (0-4)

For replacing the prewetting liquid of the step (0-3), the step of cleaning the substrate is also one preferable embodiment. It is also one embodiment of the present invention to make the step (0-4) is not needed by inserting the step (0-2).

### Step (7)

In the step (7), the substrate is further cleaned by dripping water or an organic solvent on the substrate from which the substrate surface treatment layer has been removed and removing the water or the organic solvent.

### Method for Manufacturing a Device

A device can be manufactured by further processing the substrate manufactured by the cleaning method according to the present invention. Known methods can be used for the processing. The processed substrate can be, if desired, cut into chips, connected to a lead frame, and packaged with resin. Examples of the device include a semiconductor, a liquid crystal display device, an organic EL display device, a plasma display device and a solar cell device. In a preferred embodiment of the present invention, the device is a semiconductor device.

The present invention is described below with reference to various examples. The embodiment of the present invention is not limited only to these examples.

### Preparation of Substrate Surface Treating Solution

The basic compound (A) shown in Tables 1 and 2 is dissolved in DIW (B). 0.1 mass % of MEGAFACE F-410 (DIC) as the surfactant (C) is added to this, and then the mixture is sufficiently stirred. This liquid is filtered using a filter “Optimizer UPE” (Nihon Entegris, UPE, pore size: 10 nm) to obtain the substrate surface treating solutions of Examples 1 to 31 and Comparative Examples 2 to 4.

The concentration (mass %) of the basic compound (A) with respect to the substrate surface treating solution is as shown in Tables 1 and 2. In Comparative Example 1, the component is only DIW (100%). The component corresponding to the basic compound (A) of Comparative Examples 2 to 4 is a representation for comparison, and the component actually used is an acid.

### [Table 1]

TABLE 1

| | | | | Evaluation of | Evaluation |
|---|---|---|---|---|---|
| | | | | removal of | of |
| | | | Contact | substrate | particles |
| Example | Basic compound (A) | | angle | cleaning film | removal |
| 1 | Polyallylamine (Mw = 1000) | 5.00% | A | AA | AA |
| 2 | Polyallylamine (Mw = 500) | 5.00% | A | AA | AA |
| 3 | Polyallylamine (Mw = 5000) | 5.00% | A | A | A |
| 4 | Polyallylamine (Mw = 10000) | 5.00% | A | A | A |
| 5 | Polyallylamine (Mw = 1000) | 1.00% | A | AA | AA |
| 6 | Polyallylamine (Mw = 1000) | 0.10% | A | AA | AA |
| 7 | Polyallylamine (Mw = 1000) | 50.00% | A | AA | AA |
| 8 | Polyethyleneimine (Mw = 300) | 5.00% | A | AA | AA |
| 9 | Polyethyleneimine (Mw = 300) | 1.00% | A | AA | AA |
| 10 | Polyethyleneimine (Mw = 300) | 0.10% | A | AA | AA |
| 11 | Polyethyleneimine (Mw = 300) | 99.00% | A | AA | AA |
| 12 | Polyethyleneimine(Mw = 100) | 5.00% | A | AA | AA |
| 13 | Polyethyleneimine (Mw = 1000) | 5.00% | A | AA | AA |
| 14 | Polyethyleneimine (Mw = 5000) | 5.00% | A | A | A |
| 15 | Polyethyleneimine (Mw = 10000) | 5.00% | A | A | A |
| 16 | Polydiallylamine (Mw = 1000) | 5.00% | A | AA | AA |
| 17 | 1,4-Diaminobutane | 5.00% | A | AA | A |
| 18 | N,N′-Bis(3- | 5.00% | A | AA | A |
| | aminopropyl)ethylenediamine | | | | |
| 19 | Diallylamine | 5.00% | A | AA | A |
| 20 | Triallylamine | 5.00% | A | AA | A |
| 21 | 1,4-Diazabicyclo[2.2.2]octane | 5.00% | A | AA | A |
| 22 | N,N,N′,N″,N″- | 5.00% | A | AA | A |
| | Pentamethyldiethylenetriamine | | | | |
| 23 | N,N,N′,N′- | 5.00% | A | AA | A |
| | Tetramethylethylenediamine | | | | |
| 24 | 2,6,10-Trimethyl-2,6,10- | 5.00% | A | AA | A |
| | triazaundecane | | | | |
| 25 | N,N,N′,N′-Tetramethyl-1,3- | 5.00% | A | AA | A |
| | diaminopropane | | | | |
| 26 | 1,1,4,7,10,10- | 5.00% | A | AA | A |
| | Hexamethyltriethylenetetramine | | | | |
| 27 | 2-(2-Aminoethylamino)ethanol | 5.00% | A | AA | A |
| 28 | Diethanolamine | 5.00% | A | AA | A |
| 29 | Hexamethylenetetramine | 5.00% | A | AA | A |
| 30 | 2-(Butylamino)ethanol | 5.00% | A | AA | A |
| 31 | N-Benzylethanolamine | 5.00% | A | AA | A |

In the table:
polyallylamine 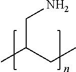
polyethyleneimine 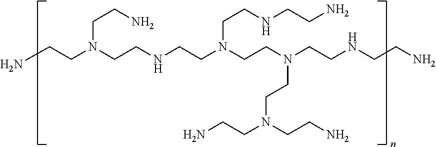
polydiallylamine

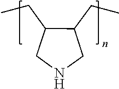

TABLE 2

| | | | | | Evaluation of | Evaluation |
|---|---|---|---|---|---|---|
| | | | | | removal of | of |
| | | | | Contact | substrate | particles |
| | | Basic compound (A) | | angle | cleaning film | removal |
| Comparative | 1 | None | — | B | B | D |
| Example | 2 | Acetic acid | 5.00% | B | B | D |
| | 3 | Sulfuric acid | 5.00% | B | B | D |
| | 4 | Hydrochloric acid | 5.00% | B | B | D |

### Preparation of Substrate Cleaning Solution

DIW and IPA are mixed at a volume ratio of 10:90. This is used as the solvent (c). Novolak (Mw: about 5,000) as an insoluble or hardly soluble solute (a) and polyacrylic acid (Mw: about 15,000) as a soluble solute (b) are added to the solvent (c) so that the solid components (sum of the components (a) and (b)) in the substrate cleaning solution becomes 5.0 mass %. The mass ratio of (a):(b) is 100:5. This is stirred with a stirrer for 1 hour to obtain a liquid having a solid component concentration of 5 mass %. This liquid is filtered using a filter “Optimizer UPE” to obtain a substrate cleaning solution.

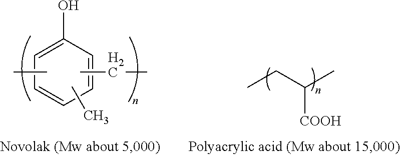

### Substrate for Evaluation

On a 12-inch Si bare substrate, a film is formed by CVD with a mixed gas of CH₄ and Argon at room temperature to 120° C. As a result, amorphous carbon of about 70 nm is formed on the substrate. Hereinafter, this is taken as an a-C substrate. In the measurement of the contact angle and the evaluation of the removal of the substrate cleaning film, an a-C substrate cut out into a 3 cm square is used.

### Contact Angle

When measured by the sessile drop method using a contact angle meter (“Dropmaster700”, Kyowa Interface Science), the static contact angle of the a-C substrate is 50°.

Using a spin coater (“MS-A100”, Mikasa), 10 cc of the above-mentioned substrate surface treating solution is dripped on the a-C substrate and coated by rotation at 1,500 rpm. Then, 50 cc of DIW is dripped on the substrate, and the substrate is rotated at 1,500 rpm o form a substrate surface treatment layer.

The contact angle of the substrate on which the substrate surface treatment layer is formed is measured in the same manner as above and evaluated according to the following criteria. The results obtained are as shown in Tables 1 and 2.
A: The contact angle is less than 40°.
B: The contact angle is 40° or more.

### Evaluation of Removal of Substrate Cleaning Film

Using “MS-A100”, 10 cc of the above-mentioned substrate surface treating solution is dripped on the a-C substrate and coated by rotation at 1,500 rpm. Then, 50 cc of DIW is dripped on the substrate, and the substrate is rotated at 1,500 rpm to form a substrate surface treatment layer. Then, 1 cc of the above-mentioned substrate cleaning solution is dripped and coated by rotation at 1,500 rpm to form a substrate cleaning film. 50 cc of 5.0 mass % ammonia water is dripped as a remover (1) on the formed substrate cleaning film to remove the substrate cleaning film. With respect to the substrate in this state, the remaining film amount of the substrate surface treatment layer is measured using an ellipsometer (“M-2000”, JA Woollam Japan) and evaluated according to the following criteria.

The results obtained are as shown in Tables 1 and 2.
AA: The remaining film amount is less than 0.5 nm.
A: The remaining film amount is 0.5 nm or more and 2.0 nm or less.
B: The remaining film amount is over 2.0 nm.

### Evaluation of Particles Removal

Particles are attached to the a-C substrate. Ultra-high purity colloidal silica (average primary particle size: about 100 nm) is used as particles for experiment. 50 mL of the silica fine particle composition is dripped, and the mixture is coated by rotating at 500 rpm for 5 seconds. Then, the solvent of the silica fine particle composition is spin-dried by rotating at 1,000 rpm for 30 seconds. As a result, a particles-attached substrate for evaluation is obtained.

Using a spin coater (“RF³”, SOKUDO), 10 cc of the above-mentioned substrate surface treating solution is dripped on the particles-attached substrate and coated by rotation at 1,500 rpm. Then, 50 cc of DIW is dripped on the substrate, and the substrate is rotated at 3,000 rpm to form a substrate surface treatment layer. Then, 50 cc of the above-mentioned substrate cleaning solution is dripped and coated by rotation at 1,500 rpm to form a substrate cleaning film. Then, while rotating the substrate at 100 rpm, 5.0 mass % ammonia water is dripped as the remover (1) for 10 seconds so as to cover the whole substrate. After maintaining that state for 20 seconds, the substrate is rotated at 1,500 rpm to remove the substrate cleaning film. Then, in order to remove the substrate surface treatment layer, 5.0 mass % acetic acid water is dripped as the remover (2) for 10 seconds so as to cover the whole substrate. By rotating the substrate at 1,000 rpm, the remover is shaken off and the substrate is dried.

Using a dark field defect inspection device (LS- 9110, Hitachi High-Tech), the remaining particles amount and the removal status of the film on these substrates are confirmed and evaluated according to the following criteria. The results obtained are as shown in Tables 1 and 2.
AA: The substrate cleaning film is removed, and the number of particles is 10 or less.
A: The substrate cleaning film is removed, and the number of particles is more than 10 and 100 or less.
B: The substrate cleaning film is removed, and the number of particles is more than 100 and 1,000 or less.
C: The substrate cleaning film is removed, and the number of particles is over 1,000.
D: All of the substrate cleaning film is not removed.

### Evaluation of Removal of Substrate Surface Treatment Layer

Using “MS-A100”, 10 cc of the above-mentioned substrate surface treating solution is dripped on the a-C substrate and coated by rotation at 1,500 rpm. Then, 50 cc of DIW is dripped on the substrate, and the substrate is rotated at 1,500 rpm to form a substrate surface treatment layer. Then, 1 cc of the above-mentioned substrate cleaning solution is dripped and coated by rotation at 1,500 rpm to form a substrate cleaning film. 50 cc of 5.0 mass % ammonia water is dripped as the remover (1) on the formed substrate cleaning film to remove the substrate cleaning film. When the substrate at this point is measured for the remaining film amount of the substrate surface treatment layer using the ellipsometer “M-2000” it is 0.2 nm.

In order to remove the substrate surface treatment layer from the above substrate, 5.0 mass % acetic acid water is dripped as the remover (2) for 10 seconds so as to cover the whole substrate. By rotating at 1,000 rpm, the remover is shaken off and the substrate is dried. When the substrate at this point is measured for the remaining film amount of the substrate surface treatment layer using the ellipsometer “M-2000”, it is 0.0 nm.

### Preparation of Substrate Surface Treating Solution 2

The basic compound (A) shown in Table 3 is added to the solvent (B), and the mixture is sufficiently stirred. This liquid is filtered using a filter “Optimizer UPE” (Nihon Entegris, UPE, pore size: 10 nm) to obtain the substrate surface treating solution of Examples 41 to 43. The concentration (mass %) of the basic compound (A) with respect to the substrate surface treating solution is as shown in Table 3.

TABLE 3

| | | | | | | Evaluation of | Evaluation |
|---|---|---|---|---|---|---|---|
| | | | | | | removal of | of |
| | | | | Solvent | Contact | substrate | particles |
| | | Basic compound (A) | | (B) | angle | cleaning film | removal |
| Example | 41 | Polyallylamine | 5.00% | EtOH | A | AA | AA |
| | | (Mw = 300) | | | | | |
| | 42 | Polyethyleneimine | 5.00% | IPA | A | AA | AA |
| | | (Mw = 600) | | | | | |
| | 43 | 1,4-Diazabicyclo[2.2.2] | 5.00% | PGME | A | AA | A |
| | | octane | | | | | |

For the substrate surface treating solutions of Examples 41 to 43, the evaluation of contact angle, the evaluation of removal of substrate cleaning film, and the evaluation of particle removal are performed in the same manner as described above. The results are shown in Table 3.

### EXPLANATION OF SYMBOLS

1. substrate
2. particle
3. substrate surface treatment layer
4. substrate cleaning film
5. remover (1) AMENDMENTS TO THE CLAIMS

1.-15. (canceled)

16. A substrate surface treating solution comprising a basic compound (A) and a solvent (B):
wherein
the substrate surface treating solution is applied on a substrate to form a substrate surface treatment layer containing at least a part of the basic compound (A), and a substrate cleaning solution is applied on the substrate surface treatment layer and used for forming a substrate cleaning film.

17. The substrate surface treating solution according to claim 16, wherein the solvent (B) comprises water (B-1); and/or
the content of water (B-1) is 50 to 100 mass % based on the solvent (B).

18. The substrate surface treating solution according to claim 16, wherein the basic compound (A) is:
a polymer comprising a repeating unit represented by the formula (A-1) or the formula (A-2); or
a compound represented by the formula (A-3) or the formula (A-4), or a saturated nitrogen-containing cyclic hydrocarbon (A-5) or a salt thereof: 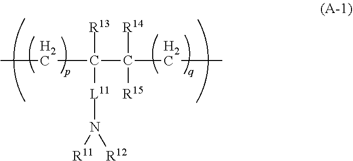
where
R¹³, R¹⁴ and R¹⁵ are each independently H, C₁₋₄ alkyl or carboxy;
L¹¹ is a single bond or C₁₋₄ alkylene;
R¹¹ is a single bond, H or C₁₋₅ alkyl;
R¹² is H, C₁₋₅ alkyl, C₁₋₅ acyl or formyl;
where at least one of —CH₂— in the alkylene of L¹¹, the alkyl of R¹¹, and the alkyl or acyl of R¹² can be each independently replaced with —NH—;
the single bond or alkyl of R¹¹ and the alkyl of R¹⁵ can be bonded together to form a saturated or unsaturated heterocycle;
the alkyl of R¹¹ and the alkyl, acyl or formyl of R¹² can be bonded together to form a saturated or unsaturated heterocycle; and
p and q are each independently numbers of 0 to 1, 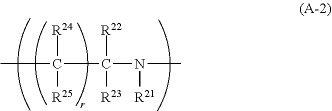
where
R²¹ is each independently H, a single bond, C₁₋₄ alkyl or carboxy;
R²², R²³, R²⁴ and R²⁵ are each independently H, C₁₋₄ alkyl or carboxy; and
r is a number of 0 to 3, 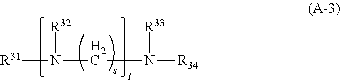
where
R³¹, R³², R³³ and R³⁴ are each independently H or methyl;
s is a number of 2 to 5; and
t is a number of 1 to 5, and 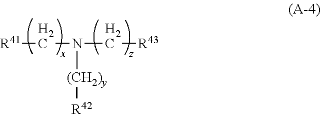
where
R⁴¹ is H, hydroxy or vinyl;
R⁴² is H hydroxy, vinyl, amino or phenyl;
R⁴³ is H, hydroxy or vinyl;
x is a number of 1 to 5;
y is a number of 1 to 5; and
z is a number of 0 to 5.

19. The substrate surface treating solution according to claim 16, further comprising a surfactant (C).

20. The substrate surface treating solution according to claim 16, further comprising a moisturizing agent (D).

21. The substrate surface treating solution according to claim 19, further comprising a moisturizing agent (D).

22. The substrate surface treating solution according to claim 21, wherein the content of the basic compound (A) is 0.001 to 99.9 mass % based on the substrate surface treating solution:
the content of the solvent (B) is 0.001 to 99.999 mass % based on the substrate surface treating solution;
the content of the surfactant (C) is 0.001 to 5 mass % based on the substrate surface treating solution; or
the content of the moisturizing agent (D) is 0.001 to 10 mass % based on the substrate surface treating solution.

23. The substrate surface treating solution according to claim 16, further comprising a further additive (E):
wherein
the further additive (E) comprises an acid, a base (excluding the basic compound (A)), an antibacterial agent, a bactericide, a preservative or an antifungal agent.

24. The substrate surface treating solution according to claim 23, wherein the content of the further additive (E) is up to 10 mass % based on the substrate surface treating solution.

25. The substrate surface treating solution according to claim 16, wherein the thickness of the substrate surface treatment layer is 0.001 to 2 nm.

26. The substrate surface treating solution according to claim 16, wherein the surface of the substrate before applying the substrate surface treating solution is hydrophobic.

27. The substrate surface treating solution according to claim 16, wherein the surface of the substrate before applying the substrate surface treating solution is hydrophobic:
the contact angle of the surface of the substrate is 30 to 90°; or
the surface of the substrate is flat or has a stepped structure.

28. The substrate surface treating solution according to claim 16, wherein the substrate cleaning solution comprises an insoluble or hardly soluble solute (a), a soluble solute (b) and a solvent (c):
the solubility of the insoluble or hardly soluble solute (a) in 5.0 mass % ammonia water is less than 100 ppm, and the solubility of the soluble solute (b) in 5.0 mass % ammonia water is 100 ppm or more.

29. The substrate surface treating solution according to claim 16, wherein the substrate cleaning film is removed by a remover (1) and the substrate surface treatment layer is removed by a remover (2).

30. A method for manufacturing a cleaned substrate comprising the following steps:
(1) applying the substrate surface treating solution according to claim 16 on a substrate;
(2) forming a substrate surface treatment layer containing at least a part of a basic compound (A) from the substrate surface treating solution;
(3) applying a substrate cleaning solution on the substrate surface treatment layer;
(4) forming a substrate cleaning film from the substrate cleaning solution;
(5) removing the substrate cleaning film with a remover (1); and
(6) removing the substrate surface treatment layer with a remover (2).

31. The method for manufacturing a cleaned substrate according to claim 30, wherein in the step (2), the substrate surface treatment layer having a film thickness of 0.001 to 2 nm is formed by cleaning with an aqueous rinse.

32. The method for manufacturing a cleaned substrate according to claim 30, further comprising at least one of the following steps:
(0-1) processing a pattern on the substrate by etching, and removing the etching mask;
(0-2) cleaning the substrate;
(0-3) prewetting the substrate;
(0-4) cleaning the substrate; and
(7) further cleaning the substrate by dripping water or an organic solvent on the substrate from which the substrate surface treatment layer has been removed and by removing the water or the organic solvent.

33. The method for manufacturing a cleaned substrate according to claim 34, wherein the step (2) and/or the step (4) is performed by rotating the substrate:
the rotation is performed at 500 to 3,000 rpm for 0.5 to 90 seconds: or
the substrate has a disk shape having a diameter of 150 to 600 mm.

34. A method for manufacturing a device comprising the method for manufacturing the cleaned substrate according to claim 30.
